(19) United States
(12) Patent Application Publication
(10) Pub. No.: US 2025/0169149 A1
(43) Pub. Date: May 22, 2025

(54) THIN FILM TRANSISTOR, MANUFACTURING METHOD THEREOF, AND DISPLAY APPARATUS COMPRISING THE SAME

(71) Applicant: LG Display Co., Ltd., Seoul (KR)

(72) Inventors: HyeJi JEON, Paju-si (KR); Soyang CHOI, Paju-si (KR); Yubeen LIM, Paju-si (KR); Youngjin YI, Paju-si (KR)

(73) Assignee: LG Display Co., Ltd., Seoul (KR)

(21) Appl. No.: 18/790,075

(22) Filed: Jul. 31, 2024

(30) Foreign Application Priority Data
Nov. 21, 2023 (KR) 10-2023-0162292

(51) Int. Cl. H01L 29/423; H01L 29/417; H01L 29/66; H01L 29/786; H10K 59/121

(52) U.S. Cl. CPC H10D 64/514; H10D 30/6729; H10D 30/6755; H10D 99/00; H10K 59/1213

(57) ABSTRACT

A thin film transistor includes a buffer layer on a base substrate and having a trench; an active layer on the buffer layer; and a gate electrode overlapping the active layer. The active layer includes a channel area, a source area, and a drain area. The trench includes a first trench having the source area therein, and a second trench having the drain area therein. The channel area includes a first channel area, a second channel area on one side of the first channel area and in the first trench, and a third channel area on the other side of the first channel area and in the second trench. A distance between the upper surface of the base substrate and the second channel area is shorter than a shortest distance between the upper surface of the base substrate and the first channel area.

### CROSS-REFERENCE TO RELATED APPLICATIONS

This application claims the benefit of priority of the Korean Patent Application No. 10-2023-0162292 filed on Nov. 21, 2023, which is hereby incorporated by reference as if fully set forth herein.

### BACKGROUND

### Technical Field

The present disclosure relates to a thin film transistor, a method of manufacturing the same, and a display apparatus including the same.

### Discussion of the Related Art

Transistors are widely used as switching devices or driving devices in the field of electronic devices. In particular, because a thin film transistor may be manufactured on a glass substrate or a plastic substrate, it is widely used as a switching device of a display apparatus such as a liquid crystal display apparatus or an organic light emitting device.

Based on the material constituting the active layer, thin film transistors can be divided into amorphous silicon thin film transistors using amorphous silicon as the active layer, polycrystalline silicon thin film transistors using polycrystalline silicon as the active layer, and oxide semiconductor thin film transistors using oxide semiconductors as the active layer.

The amorphous silicon thin film transistor (a-Si TFT) has the advantage of short manufacturing process time and low production cost because amorphous silicon can be deposited in a short time to form an active layer, but has the disadvantage of being limited in use in active matrix organic light emitting devices (AMOLEDs) because of low mobility and poor current driving ability and a change in threshold voltage.

Polycrystalline silicon thin film transistor (poly-Si TFT) is made by crystallizing amorphous silicon after amorphous silicon is deposited. Because a process of crystallizing amorphous silicon is required in the manufacturing process of a polycrystalline silicon thin film transistor, the manufacturing cost increases as the number of processes increases, and because the crystallization process is performed at a high process temperature, it is difficult to apply the polycrystalline silicon thin film transistor to a large area device. In addition, due to its polycrystalline properties, it is difficult to secure the uniformity of the polycrystalline silicon thin film transistor.

In an oxide semiconductor thin film transistor (TFT), because the oxide constituting the active layer can be formed at a relatively low temperature, has high mobility, and has a large resistance change according to the oxygen content, desired physical properties can be easily obtained. Also, due to the nature of the oxide, because the oxide semiconductor is transparent, it is also advantageous to implement a transparent display.

In the oxide semiconductor, when doping for conductorization occurs, a conductorization region is unnecessarily formed by doping. Therefore, it may be difficult to optimize a threshold voltage (Vth) of the thin film transistor within the same process.

Therefore, technologies for controlling the depth of conductorization penetration are continuously being studied.

### SUMMARY

Accordingly, embodiments of the present disclosure are directed to a thin film transistor, a method of manufacturing the same, and a display apparatus including the same that substantially obviates one or more of the problems due to limitations and disadvantages of the related art.

An aspect of the present disclosure is to provide a thin film transistor that includes a trench to maintain the length of an effective channel and to control or prevent conductorization diffusion.

Another aspect of the present disclosure is to provide a thin film transistor that includes a trench to prevent or suppress the threshold voltage Vth from being shifted in the negative (−) direction even if the channel area has a short channel.

Another aspect of the present disclosure is to provide a display apparatus including such a thin film transistor.

Another aspect of the present disclosure is to provide a method of manufacturing such a thin film transistor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor may comprise a base substrate; a buffer layer on the base substrate, an upper surface of the buffer layer having a trench; an active layer on the buffer layer; and a gate electrode spaced apart from the active layer and at least partially overlapping the active layer in a plan view; wherein the active layer includes: a channel area that overlaps the gate electrode in the plan view; a source area connected to one side of the channel area in the plan view; and a drain area connected to the other side of the channel area in the plan view; wherein the trench includes: a first trench having the source area therein; and a second trench having the drain area therein; wherein the channel area includes: a first channel area; a second channel area on one side of the first channel area, in contact with the source area, and in the first trench; and a third channel area on the other side of the first channel area, in contact with the drain area, and in the second trench; wherein a shortest distance between an upper surface of the base substrate and the second channel area is shorter than a shortest distance between the upper surface of the base substrate and the first channel area, and wherein a shortest distance between the upper surface of the base substrate and the third channel area is shorter than the shortest distance between the upper surface of the base substrate and the first channel area.

In another aspect, a manufacturing method of a thin film transistor may comprise forming a first insulating material on a base substrate and patterning the first insulating material to form a buffer layer including a trench; forming an active layer on the buffer layer; forming a second insulating material on the active layer and forming a first gate insulating layer by patterning the second insulating material; forming a second gate insulating layer on the first gate insulating layer; and forming a gate electrode on the second gate insulating layer, wherein at least a portion of the trench overlaps the gate electrode in a plan view.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view of a thin film transistor according to an embodiment of the present disclosure.

FIG. 2 is a cross-sectional view taken along line I-I′ of FIG. 1.

FIG. 3 is a cross-sectional view of a thin film transistor according to another embodiment.

FIG. 4 is a cross-sectional view of a thin film transistor according to another embodiment.

FIGS. 5A to 5G are process diagrams showing a process of manufacturing a thin film transistor according to an embodiment of the present disclosure.

FIG. 6 is a schematic view of a display apparatus according to an embodiment of the present disclosure.

FIG. 7 is a circuit diagram of any one pixel of FIG. 6.

FIG. 8 is a plan view of the pixel of FIG. 7.

FIG. 9 is a cross-sectional view taken along line II-II' of FIG. 8.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle, and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where “comprise,” “have,” and “include” described in the present disclosure are used, another portion may be added unless “only˜” is used. The terms of a singular form may include plural forms unless referred to the contrary.

In construing an element, the element is construed as including an error band although there is no explicit description.

In describing a position relationship, for example, when the position relationship between two portions is described as “upon˜,” “above˜,” “below˜,” and “next to˜,” one or more other portions may be disposed between the two portions unless “just” or “directly” is used.

Spatially relative terms such as “below,” “beneath,” “lower,” “above,” and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “directly” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one embodiment may be a drain electrode in another embodiment, and the drain electrode of any one embodiment may be a source electrode in another embodiment.

In some embodiments of the present disclosure, for convenience of description, a source area is distinguished from a source electrode, and a drain area is distinguished from a drain electrode, but embodiments of the present disclosure are not limited thereto. The source area may be the source electrode, and the drain area may be the drain electrode. In addition, the source area may be the drain electrode, and the drain area may be the source electrode.

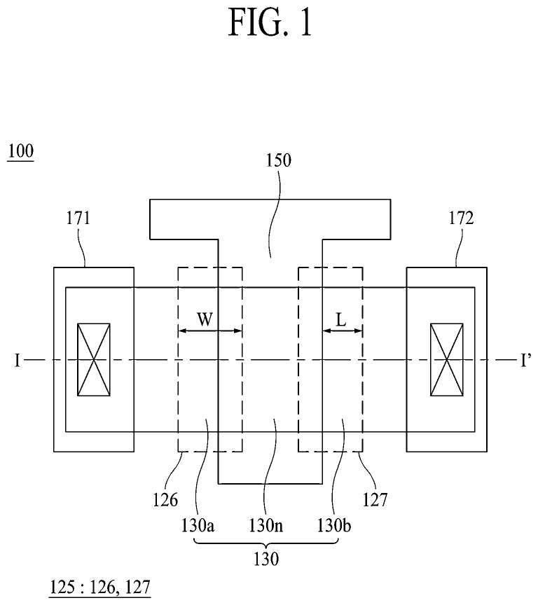

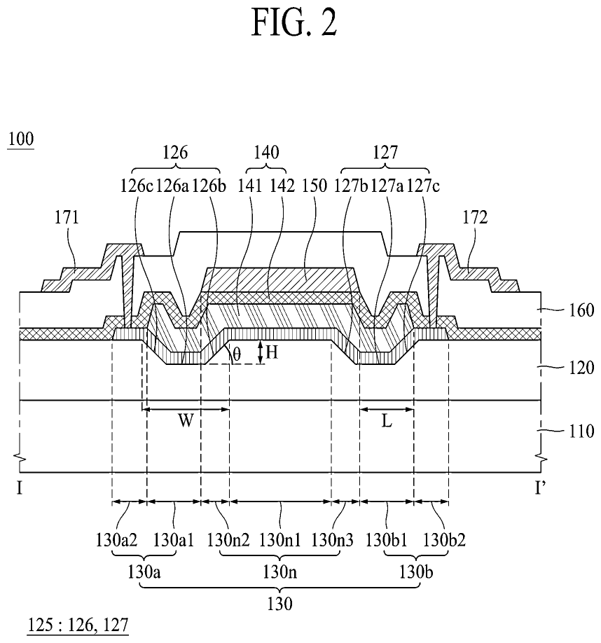

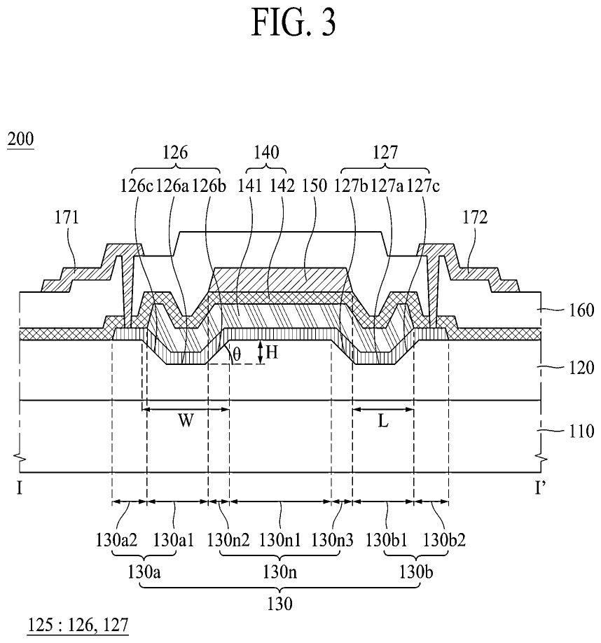

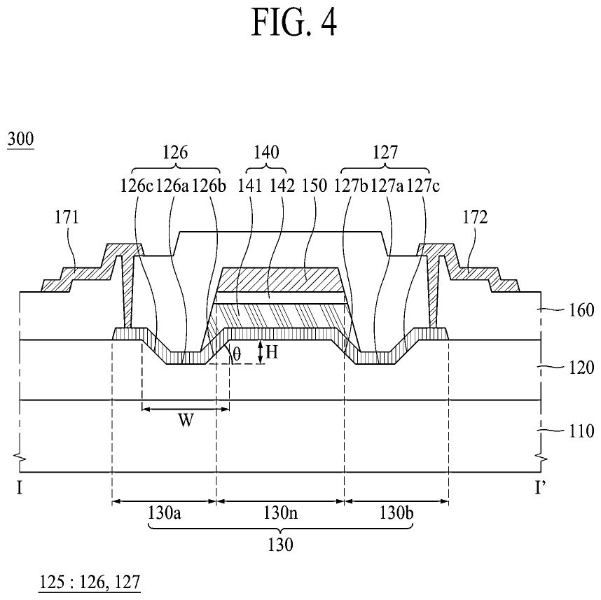

FIG. 1 is a plan view of a thin film transistor 100 according to an embodiment of the present disclosure. FIG. 2 is a cross-sectional view taken along line I-I′ of FIG. 1. FIG. 3 is a cross-sectional view of a thin film transistor 200 according to another embodiment. FIG. 4 is a cross-sectional view of a thin film transistor 300 according to another embodiment.

As shown in FIGS. 1 and 2, the buffer layer 120 on the base substrate 110, the active layer 130 on the buffer layer 120, and the gate electrode 150 spaced apart from the active layer 130 and overlapping at least partially with the active layer 130 may be included. According to an example embodiment, the thin film transistor 100 may further include a base substrate 110. In FIGS. 1 and 2, the buffer layer 120 is disposed on the base substrate 110.

According to an embodiment, the thin film transistor 100 may further include a gate insulating layer 140. With reference to FIGS. 1 and 2, the gate insulating layer 140 is disposed on the active layer 130. For example, the gate insulating layer 140 may be disposed between the active layer 130 and the gate electrode 150.

According to an embodiment, another layer of the thin film transistor 100 may be additionally disposed on the gate electrode 150. In detail, the thin film transistor 100 may further include an interlayer insulating layer 160. In FIG. 2, the interlayer insulating layer 160 is disposed on the gate electrode 150. In detail, the gate electrode 150 is disposed between the gate insulating layer 140 and the interlayer insulating layer 160.

According to an embodiment of the present disclosure, the thin film transistor 100 may further include a source electrode 171 and a drain electrode 172. As shown in FIGS. 1 and 2, the source electrode 171 and the drain electrode 172 are disposed on the interlayer insulating layer 160.

Hereinafter, components of the thin film transistor 100 according to an embodiment of the present disclosure will be described in more detail.

Glass or plastic may be used for the base substrate 110. Transparent plastic having flexible characteristics, for example, polyimide, may be used as plastic.

When the polyimide is used as the base substrate 110, considering that a high-temperature deposition process is performed on the base substrate 110, a heat-resistant polyimide capable of withstanding a high temperature may be used. In this case, in order to form a thin film transistor, processes such as deposition, etching, and the like may be performed in a state in which the polyimide substrate is disposed on the carrier substrate made of a high-durable material such as glass.

As illustrated in FIGS. 1 and 2, a buffer layer 120 may be disposed on the base substrate 110. The buffer layer 120 is formed on the base substrate 110 and may be formed of an inorganic material or an organic material. For example, an insulating oxide such as silicon oxide (SiOx), aluminum oxide (Al₂O₃) and the like may be included. The buffer layer 120 protects the active layer 130 by blocking impurities such as moisture and oxygen introduced from the base substrate 110, serves to flatten the upper portion of the base substrate 110, and may be formed as a single layer or a plurality of layers.

According to an embodiment, the buffer layer 120 may include a trench 125. The trench 125 may refer to a region partially etched in the buffer layer 120.

As shown in FIGS. 1 and 2, an active layer 130 may be disposed on the buffer layer 120. The active layer 130 may include a channel area 130n, a source area 130a, and a drain area 130b. The channel area 130n overlaps the gate electrode 150. The channel area 130n serves as a channel of the thin film transistor 100. For example, the active layer 130 may include a channel area 130n overlapping the gate electrode 150 in a plane view, a source area 130a connected to one side of the channel area 130n without overlapping the gate electrode 150 in a plane view, and a drain area 130b connected to the other side of the channel area 130n without overlapping the gate electrode 150 in a plane view. According to an embodiment, the source area 130a and the drain area 130b are spaced apart from each other with the channel area 130n interposed therebetween.

According to a configuration, the active layer 130 may be formed of a semiconductor material. The active layer 130 may include an oxide semiconductor material. The oxide semiconductor material may include at least one of an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material. However, embodiments of the present disclosure are not limited thereto, and the active layer 130 may be made of another oxide semiconductor material known in the art.

The source area 130a and the drain area 130b may be formed by selective conductorization with respect to the active layer 130 made of a semiconductor material. According to an embodiment, imparting conductivity to a specific portion of the active layer 130 so that it may function as a conductor is referred to as selective conductorization. By this selective conductorization, a portion to which conductivity is imparted is made into a conductor, and a portion to which conductivity is not imparted is not made into a conductor.

The source area 130a and the drain area 130b illustrated in FIGS. 1 and 2 may be portions to which conductivity is imparted by selective conductorization. According to an embodiment of the present disclosure, selective conductorization may be achieved by doping using a dopant. In addition, selective conductorization may be achieved by plasma treatment.

For example, the active layer 130 may be selectively conductorized by dopant doping or dopant implantation using the gate electrode 150 or a photoresist as a mask. The dopant may include at least one of boron (B), phosphorus (P), fluorine (F), and hydrogen (H), for example.

When the active layer 130 is selectively conductorized by dopant doping, a dopant-doped region of the active layer 130 is selectively conductorized to become a source area 130a or a drain area 130b. A region of the active layer 130 that is not doped with a dopant may not be conductorized and may become a channel area 130n.

Alternatively, the active layer 130 may be selectively conductorized by plasma treatment applied to the process of patterning the gate insulating layer 140. For example, plasma may be used in the process of patterning the gate insulating layer 140, and a portion of the active layer 130 in contact with the plasma may be selectively conductorized to become the source area 130a or the drain area 130b of the active layer 130. A portion of the active layer 130 that is protected by the gate insulating layer 140 and does not contact the plasma may not be conductorized, and may be a channel area 130n.

However, for selective conductorization, when doping using dopants is performed, a problem in that the conductorization region is diffused and the conductorization region is unnecessarily formed by doping may occur. As a result, a problem in which the threshold voltage (Vth) of the thin film transistor is shifted in the negative (−) direction may occur, and a problem in which device deterioration may occur.

To prevent or at least reduce the problem above, the buffer layer 120 including the trench 125 may be formed, and the active layer 130 may be formed on the trench 125. FIG. 1 and FIG. 2 illustrate a structure in which the active layer 130 is formed on the buffer layer 120 and the trench 125. At least a portion of the trench 125 according to an embodiment may overlap the gate electrode 150. The trench 125 according to an embodiment includes a first trench 126 overlapping the source area 130a and a second trench 127 overlapping the drain area 130b. In this case, the first trench 126 and the second trench 127 are disposed to be spaced apart from each other.

When the active layer 130 is formed on the trench 125 having a constant inclined surface, the active layer 130 may also have a constant inclined surface. When at least a portion of the trench 125 overlaps the gate electrode 150 and the channel area 130n of the active layer 130 has a constant inclined surface, conductorization diffusion into the inclined channel area 130n may be controlled or prevented, and thus, the channel area 130n may be further secured, thereby controlling or preventing conductorization diffusion while maintaining the length of the effective channel.

As a result, even if the channel area 130n has a short channel, the threshold voltage (Vth) may be prevented or suppressed from being shifted in the negative (−) direction, and the device may be prevented or suppressed from deteriorating.

According to an embodiment, at least a portion of the trench 125 may overlap any one of the source area 130a and the drain area 130b when viewed in a plan view. The trench 125 may include a first trench 126 overlapping the source area 130a and a second trench 127 overlapping the drain area 130b.

In general, when conductorization with respect to the source area 130a and the drain area 130b is performed, conductorization diffusion from an interface between the channel area 130n and the conductorization portion toward the channel area 130n may be greatly progressed. If conductorization diffusion is greatly progressed toward the channel area 130n, a threshold voltage (Vth) of the thin film transistor 100 may move in a negative (−) direction, and thus driving stability of the thin film transistor 100 may be deteriorated.

However, according to an embodiment of the present disclosure, when the first trench 126 overlaps the source area 130a, the second trench 127 overlaps the drain area 130b, and at the same time the first trench 126 and the second trench 127 overlap the gate electrode 150, the first trench 126 and the second trench 127 are disposed at the boundary between the channel area 130n and the source area 130a and the boundary between the channel area 130n and the drain area 130b, respectively. Accordingly, the channel area 130n of the active layer 130 disposed on the first trench 126 and the second trench 127 and having a predetermined inclined surface is disposed in the region adjacent to the boundary between the channel area 130n and the source area 130a and the boundary between the channel area 130n and the drain area 130b, thereby controlling or preventing the diffusion of conduction.

According to an embodiment, the channel area 130n may include a first channel area 130nl, a second channel area 130n2, and a third channel area 130n3. The channel area 130n includes the first channel area 130n1, which serves as an effective channel, the second channel area 130n2 disposed on one side of the first channel area 130n1, in contact with the source area 130a, and disposed in the first trench 126, and the third channel area 130n3 disposed on the other side of the first channel area 130n1, in contact with the drain area 130b, and disposed in the second trench 127.

In FIG. 2, an arrangement structure of the first channel area 130n1, the second channel area 130n2, and the third channel area 130n3 is illustrated.

According to an embodiment, the shortest distance between the upper surface of the base substrate 110 and the second channel area 130n2 and the third channel area 130n3 may be shorter than the shortest distance between the upper surface of the base substrate 110 and the first channel area 130n1. In detail, a thickness of the buffer layer 120 overlapping the second channel area 130n2 and the third channel area 130n3 may be less than a thickness of the buffer layer overlapping the first channel area 130n1.

When the shortest distance between the upper surface of the base substrate 110 and the second channel area 130n2 and the third channel area 130n3 is shorter than the shortest distance between the upper surface of the base substrate 110 and the first channel area 130n1, the second channel area 130n2 and the third channel area 130n3 have a predetermined inclined surface compared to the first channel area 130n1, and conductorization diffusion may be controlled or prevented into the inclined channel area 130n, thereby further securing the channel area 130n, and thus conductorization diffusion may be controlled or prevented while maintaining the length of the effective channel.

According to an embodiment, each of the first trench 126 and the second trench 127 have the first surfaces 126a and 127a parallel to the upper surface of the base substrate 110, the second surfaces 126b, 127b connected to one side of the first surfaces 126a, 127a, inclined at a predetermined angle compared to the first surfaces 126a, 127a, and third surfaces 126c and 127c connected to the other side of the first surfaces 126a, 127a, inclined at a predetermined angle compared to the first surfaces 126a, 127a.

In FIG. 2, the active layer 130 is disposed on the first surfaces 126a and 127a, the second surfaces 126b and 127b, and the third surfaces 126c and 127c of the first and second trenches 126 and 127, and the first surfaces 126a and 127a of the first and second trenches 126 and 127 are disposed between the second surfaces 126b and 127b and the third surfaces 126c and 127c.

According to an embodiment, at least a part of the second surfaces 126b and 127b of the first trench 126 and the second trench 127 may overlap the gate electrode 150.

In FIG. 2, a configuration in which at least a portion of the second surfaces 126b and 127b of the first trench 126 and the second trench 127 overlap the gate electrode 150 is illustrated. However, embodiments of the present disclosure are not limited thereto, and a portion of the second surfaces 126b and 127b of the first trench 126 and the second trench 127 may overlap the gate electrode 150 (see FIG. 4), and the entire second surfaces 126b and 127b of the first trench 126 and the second trench 127 may overlap the gate electrode 150 in a region overlapping the active layer 130 (see FIGS. 2 and 3).

When at least a portion of the second surfaces 126b and 127b of the first trench 126 and the second trench 127 overlaps the gate electrode 150, the active layer 130 disposed on the second surfaces 126b and 127b also overlaps the gate electrode 150, and the inclined surface of the active layer 130 may overlap the gate electrode 150. For example, the diffusion of conductorization into the inclined channel area 130n may be controlled or prevented, and thus, the channel area 130n may be further secured, thereby controlling or preventing the diffusion of conductorization while maintaining the length of the effective channel.

For example, the entire second surfaces 126b and 127b of the first trench 126 and the second trench 127 may overlap the gate electrode 150. Even when the entire second surfaces 126b and 127b of the first trench 126 and the second trench 127 overlap the gate electrode 150, the conductorization diffusion may be controlled or prevented to the inclined channel area 130n, and thus the channel area 130n may be further secured, thereby controlling or preventing the conductorization diffusion while maintaining the length of the effective channel.

According to an embodiment, a thickness of the buffer layer 120 overlapping the first surfaces 126a and 127a of the first trench 126 and the second trench 127 may be less than a thickness of the buffer layer 120 overlapping the second surfaces 126b and 127b and the third surfaces 126c and 127c of the first trench 126 and the second trench 127.

Although a configuration in which the active layer 130 is formed of a single layer is disclosed in FIGS. 1 and 2, configurations of the present disclosure are not limited thereto. The active layer 130 may have a single layer structure or a multilayer structure.

According to an embodiment, the channel area 130n, the source area 130a, and the drain area 130b of the active layer 130 may be integrally formed, and the active layer 130 may have a constant thickness. The active layer 130 may have substantially the same thickness.

The gate insulating layer 140 is disposed on the active layer 130. The gate insulating layer 140 protects the channel area 130n. The gate insulating layer 140 is disposed between the active layer 130 and the gate electrode 150.

The gate insulating layer 140 has insulating properties. The gate insulating layer 140 may include at least one of silicon oxide, silicon nitride, and metal-based oxide, for example. The gate insulating layer 140 may have a single layer structure or a multilayer structure.

According to an embodiment, the gate insulating layer 140 may include a first gate insulating layer 141 and a second gate insulating layer 142.

The gate insulating layer 140 includes a first gate insulating layer 141 on the active layer 130 and a second gate insulating layer 142 on the first gate insulating layer 141. In this case, the first gate insulating layer 141 may be disposed on the channel area 130n of the active layer 130 and the trench 125. The first gate insulating layer 141 may be disposed in the channel area 130n of the active layer 130, the first trench 126 and the second trench 127.

According to an embodiment, the thickness of the first gate insulating layer 141 may be greater than the thickness of the second gate insulating layer 142.

According to an embodiment, the first gate insulating layer 141 may be disposed on the channel area 130n of the active layer 130 and the trench 125, whereas the second gate insulating layer 142 may be disposed over the entire surface of the active layer 130 and the buffer layer 120.

In FIG. 2, a configuration in which the first source area 130al and the first drain area 130b1 are in contact with the first gate insulating layer 141 is illustrated, and a configuration in which the second source area 130a2 and the second drain area 130b2 are in contact with the second gate insulating layer 142 is illustrated.

The source area 130a may include a first source area 130al overlapping the first gate insulating layer 141 and the second gate insulating layer 142 and a second source area 130a2 overlapping the second gate insulating layer 142 without overlapping the first gate insulating layer 141. In addition, the drain area 130b may include the first drain area 130b1 overlapping the first gate insulating layer 141 and the second gate insulating layer 142 and a second drain area 130b2 overlapping the second gate insulating layer 142 without overlapping the first gate insulating layer 141.

For example, a region adjacent to the channel area 130n in the source area 130a and the drain area 130b, disposed on the trench 125 overlaps the first gate insulating layer 141 and the second gate insulating layer 142, a region separated from the channel area 130n, and is not disposed on the trench 125 does not overlap the first gate insulating layer 141, but only overlaps the second gate insulating layer 142.

When a region disposed on the trench 125 in the source area 130a and the drain area 130b overlaps the first gate insulating layer 141 and the second gate insulating layer 142, and a region not disposed on the trench 125 in the source area 130a and the drain area 130b does not overlap the first gate insulating layer 141 but only overlaps the second gate insulating layer 142, the thickness of the gate insulating layer 140 disposed on the first source area 130al and the first drain area 130b1 becomes greater than the thickness of the gate insulating layer 140 disposed on the second source area 130a2 and the second drain area 130b2, and thus, during doping for selective conductorization, the second source area 130a2 may have a higher dopant concentration than the first source area 130a1, and the second drain area 130b2 may have a higher dopant concentration than the first drain area 130b1. As a result, the dopant concentration in the area adjacent to the channel area 130n is low, and the conductorization diffusion into the channel area 130n may be controlled or prevented, thereby further securing the channel area 130n, thereby controlling or preventing the conductorization diffusion while maintaining the length of the effective channel.

However, embodiments of the present disclosure are not limited thereto, and even in a structure in which the gate insulating layer 140 covers the channel area 130n and exposes the source area 130a and the drain area 130b, at least a portion of the trench 125 overlaps the gate electrode 150, and the active layer 130 is formed on the trench 125, the diffusion of the conductorization may be controlled or prevented into the inclined channel area 130n, thereby further securing the channel area 130n, thereby controlling or preventing the diffusion of the conductorization while maintaining the length of the effective channel (see FIG. 4).

Although FIG. 4 shows a structure in which the gate insulating layer 140 is disposed with the first gate insulating layer 141 and the second gate insulating layer 142, embodiment of the present disclosure are not limited thereto, and the gate insulating layer 140 may be formed of a single layer.

According to an embodiment, the first source area 130al and the first drain area 130b1 may have a length L of 0.7 μm to 1.0 μm in the longitudinal direction of the channel area 130n. In this case, the longitudinal direction of the channel area 130n refers to a direction parallel to a direction connecting the source area 130a and the drain area 130b by the shortest distance in a plan view.

When the first source area 130al and the first drain area 130b1 have a length L greater than 1.0 μm in the longitudinal direction of the channel area 130n, an area in which the trench 125 is disposed is secured excessively, causing the conductorization region in the first source region 130al and the first drain region 130b1 may be excessively reduced. As a result, the current characteristics of the device may deteriorate.

On the other hand, when the first source area 130al and the first drain area 130b1 have a length L of less than 0.7 μm in the longitudinal direction of the channel area 130n, an area in which the trench 125 may be disposed is not sufficiently secured, and thus it may be difficult to suppress or prevent conductorization diffusion in the device.

Also, according to an embodiment, the trench 125 may have a height ratio (H/W) of 0.15 to 0.65. In this case, the height ratio (H/W) means a value obtained by dividing the height H of the trench 125 by the width W of the trench 125. The width W of the trench 125 may refer to the longest length in the longitudinal direction of the channel area 130n in a plan view, and the height H of the trench 125 may refer to the difference between the maximum distance and the minimum distance between the upper surface of the buffer layer 120 and the upper surface of the base substrate 110 in a direction perpendicular to the longitudinal direction of the channel area 130n. Thus, the height H of the trench 125 may refer to the depth of the trench 125.

The trench 125 may have a height ratio (H/W) of 0.15 to 0.65, in consideration of the step coverage of the upper deposition film of the trench 125, for example, the step coverage and the effect of preventing conductorization diffusion. On the other hand, when the trench 125 has a height ratio (H/W) greater than 0.65, the thickness of the active layer 130 deposited on the second surfaces 126b and 127b and the third surfaces 126c and 127c of the first trench 126 and the second trench 127 decreases, causing a device characteristic imbalance.

Also, when the trench 125 has a height ratio (H/W) less than 0.15, the second surfaces 126b and 127b and the third surfaces 126c and 127c of the first trench 126 and the second trench 127 may not be sufficiently secured. Because the inclined region of the channel area 130n is not sufficiently secured, the diffusion of conductorization into the channel area 130n may not be controlled or prevented.

In addition, according to one embodiment, the second surfaces 126b, 127b and third surfaces 126c and 127c of the first trench 126 and the second trench 127 may have a taper angle θ of 30 to 45° compared to the first surfaces 126a and 127a. When the first surfaces 126a and 127a of the first trench 126 and the second trench 127 are parallel to the base substrate 110 and the taper angle is 0°, the second surfaces 126b and 127b and the third surfaces 126c and 127c of the first trench 126 and the second trench 127 may have a taper angle of 30° to 45°. When the second and third surfaces 126b and 127b and 126c and 127c of the first trench 126 and the second trench 127 have a taper angle of 30 to 45°, the active layer 130 may be formed on the trench 125 to have a uniform thickness. On the other hand, when the taper angle of the second surfaces 126b, 127b and third surfaces 126c and 127c of the first trench 126 and the second trench 127 is out of the range of 30 to 45°, the thickness of the active layer 130 deposited on the second surfaces 126b, 127b and third surfaces 126c and 127c of the first trench 126 and the second trench 127 decreases, causing a disconnection.

The gate electrode 150 is disposed on the gate insulating layer 140. The gate electrode 150 overlaps the channel area 130n of the active layer 130. The gate electrode 150 may include at least one among an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, and chromium (Cr), tantalum (Ta), neodium (Nd), and titanium (Ti). The gate electrode 150 may have a multilayer structure including at least two conductive layers each having different physical properties. For example, the gate electrode 150 may include at least one of molybdenum (Mo) and titanium (Ti).

According to an embodiment, the gate insulating layer 140 may be patterned by etching using the gate electrode 150 as a mask, and in this process, the active layer 130 may be selectively conductorized to form the source area 130a and the drain area 130b. According to an embodiment, a region of the active layer 130 overlapping the gate electrode 150 is not conductorized to become a channel area 130n having semiconductor characteristics, and a region that does not overlap the gate electrode 150 may be conductorized to become the source area 130a and the drain area 130b.

As illustrated in FIG. 2, the interlayer insulating layer 160 may be disposed on the gate electrode 150. The interlayer insulating layer 160 may be made of an organic or inorganic insulating material. The interlayer insulating layer 160 may be formed of a composite layer of an organic layer and an inorganic layer.

According to an embodiment, the thin film transistor 100 may include a source electrode 171 and a drain electrode 172 disposed on the interlayer insulating layer 160. Positions of the source electrode 171 and the drain electrode 172 may be exchanged with each other. However, embodiments of the present disclosure are not limited thereto, and the source area 130a and the drain area 130b may serve as source and drain electrodes, respectively.

With reference to FIGS. 1 and 2, each of the source electrode 171 and the drain electrode 172 may be connected to the active layer 130 through a contact hole. The source electrode 171 may be in contact with the source area 130a through a contact hole. The drain electrode 172 may be spaced apart from the source electrode 171 to be in contact with the drain area 130b through a contact hole.

Although not shown in the drawings, a light blocking layer may be disposed on the base substrate 110. In detail, the light blocking layer may be disposed between the base substrate 110 and the active layer 130. The light blocking layer may overlap the channel area 130n. The light blocking layer protects the channel area 130n by blocking light incident from the outside.

The light blocking layer may be formed of a material having light blocking characteristics. The light blocking layer may include at least one of an aluminum-based metal such as aluminum (Al) or an aluminum alloy, a molybdenum-based metal such as molybdenum (Mo) or a molybdenum alloy, chromium (Cr), tantalum (Ta), neodium (Nd), titanium (Ti), and iron (Fe). According to an embodiment, the light blocking layer may have electrical conductivity.

The light blocking layer may be omitted. Although not shown in FIGS. 1, 2, and 3, a buffer layer may be additionally disposed between the base substrate 110 and the light blocking layer. The light blocking layer may be electrically connected to one of the source electrode 171 and the drain electrode 172.

Hereinafter, a method of manufacturing the thin film transistor 100 according to an embodiments of the present disclosure will be described.

According to an embodiment, the method of manufacturing the thin film transistor 100 may include forming the first insulating material 121 on the base substrate 110, patterning the first insulating material 121 to form the buffer layer 120 including the trench 125, forming the active layer 130 on the buffer layer 120, forming the second insulating material 141a on the active layer 130, forming the first gate insulating layer 141 by patterning the second insulating material 141a, forming the second gate insulating layer 142 on the first gate insulating layer 141, and forming the gate electrode 150 on the second gate insulating layer 142.

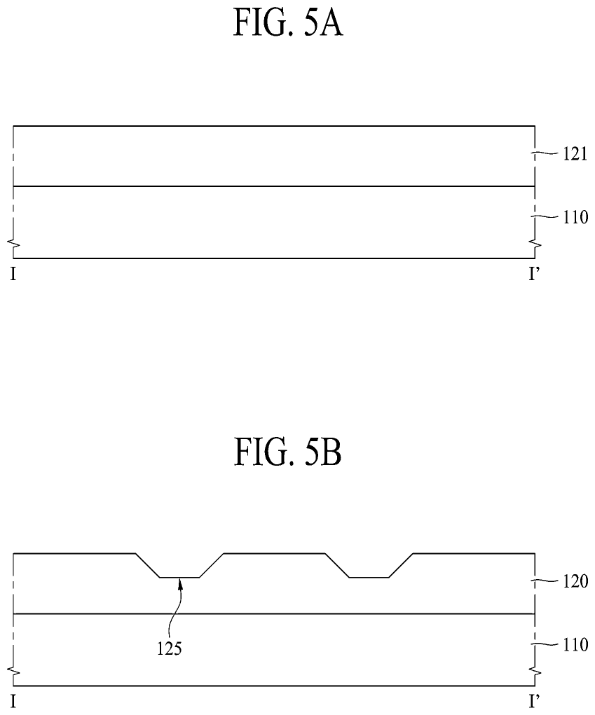

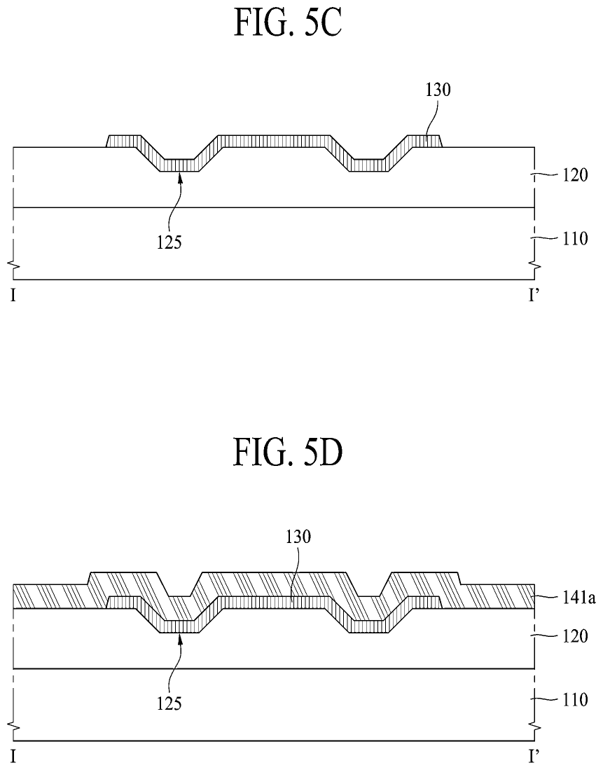

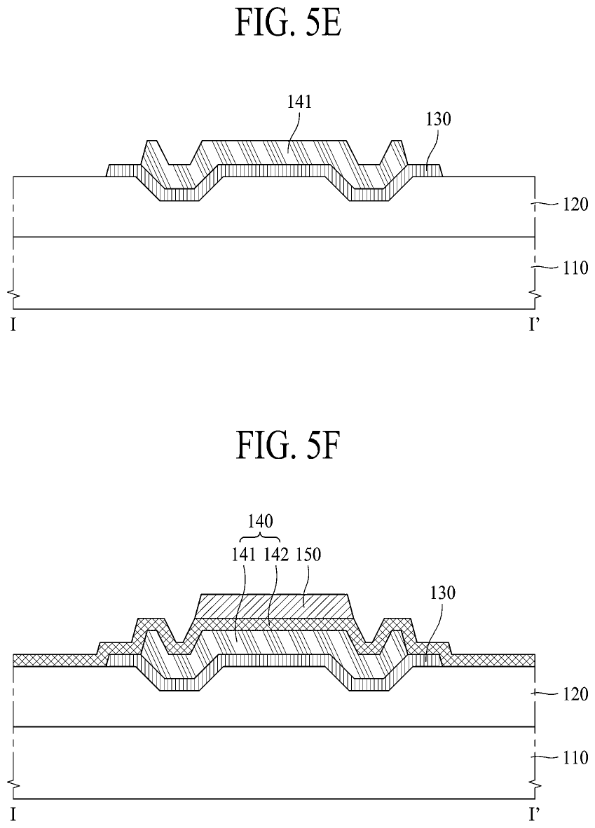

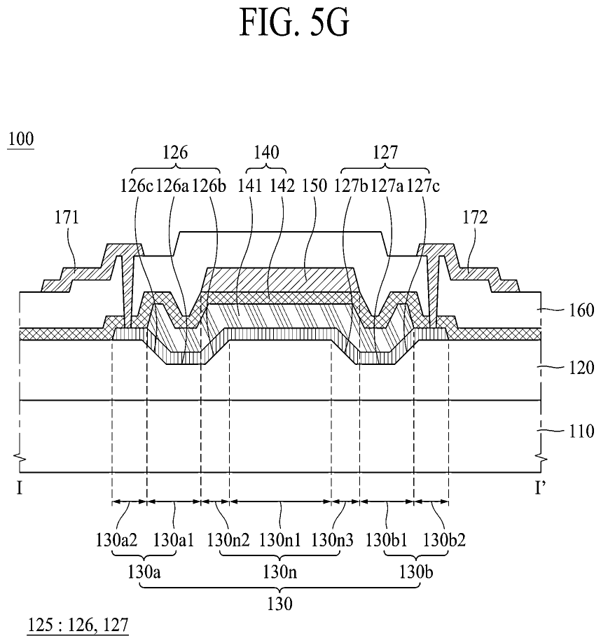

FIGS. 5A to 5G are process diagrams of a method of manufacturing the thin film transistor 100 according to an embodiment of the present disclosure. FIGS. 5A to 5G correspond to cross-sectional views taken along line I-I′ of FIG. 1.

In FIG. 5A, a first insulating material 121 is formed on the base substrate 110. For example, the first insulating material 121 is disposed on the entire surface of the base substrate 110.

In FIG. 5B, a buffer layer 120 including a trench 125 is formed by patterning the first insulating material 121.

In FIG. 5C, an active layer 130 is formed on the buffer layer 120.

In FIG. 5D, a second insulating material 141a is formed on the active layer 130. For

example, the second insulating material 141a is formed on the entire surface of the active layer 130 and on the buffer layer 120 on which the active layer 130 is not disposed.

In FIG. 5E, the second insulating material 141a is patterned to form a first gate insulating layer 141. In this case, the first gate insulating layer 141 may overlap a portion of the active layer 130 and may not overlap another portion of the active layer 130.

In FIG. 5F, the second gate insulating layer 142 is formed on the first gate insulating layer 141, and the gate electrode 150 is formed on the second gate insulating layer 142. For example, the second gate insulating layer 142 is disposed on the entire surface of the first gate insulating layer 141 and on the active layer 130 and the buffer layer 120 on which the first gate insulating layer 141 is not disposed.

In FIG. 5G, an interlayer insulating layer 160 is formed on the gate electrode 150, and a source electrode 171 and a drain electrode 172 are formed on the interlayer insulating layer 160, respectively. In this case, each of the source electrode 171 and the drain electrode 172 is in contact with at least a portion of the active layer 130.

According to an embodiment, a step of doping the active layer 130 with the dopant after the step of forming the gate electrode 150 may be further included. The dopant doped into the active layer 130 may include at least one of boron (B), phosphorus (P), fluorine (F), and hydrogen (H), for example. In this case, a region of the active layer 130 overlapping the first gate insulating layer 141 and the second gate insulating layer 142 at the same time is classified into a first source area 130a1 and a first drain area 130b1 due to a low dopant concentration, and a region that does not overlap the first gate insulating layer 141 but overlaps only the second gate insulating layer 142 is classified into a second source area 130a2 and a second drain area 130b2 due to a high dopant concentration.

The descriptions of configurations of the thin film transistor 100 may overlap with the above and omitted in the following descriptions.

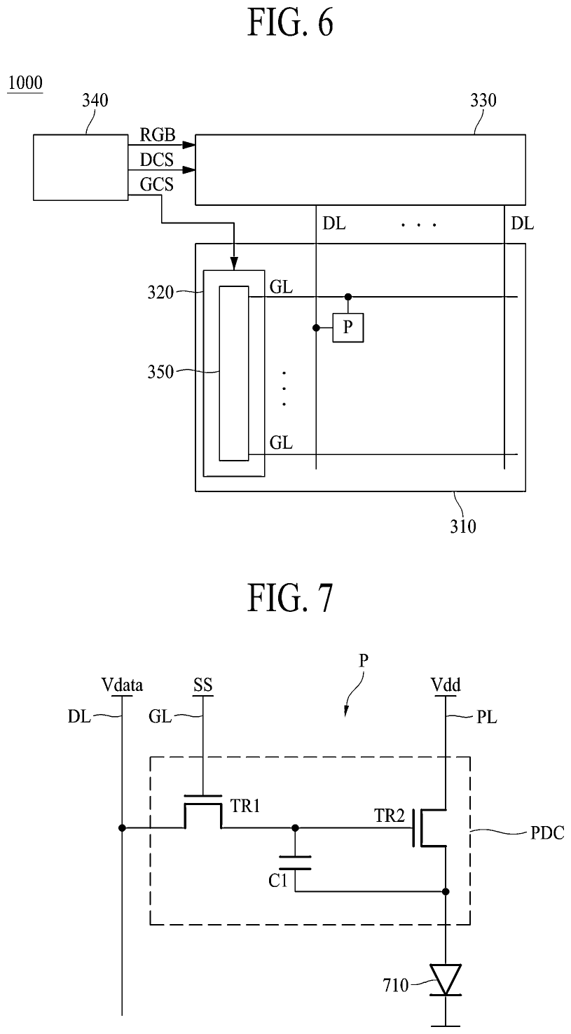

FIG. 6 is a schematic diagram illustrating a display apparatus 1000 according to further still another embodiment of the present disclosure.

As shown in FIG. 6, the display apparatus 1000 may include a display panel 310, a gate driver 320, a data driver 330 and a controller 340. The display panel 310 includes gate lines GL and data lines DL, and pixels P are disposed in intersection areas of the gate lines GL and the data lines DL. An image is displayed by driving of the pixels P. The gate lines GL, the data lines DL and the pixels P may be disposed on the base substrate 110.

The controller 340 controls the gate driver 320 and the data driver 330. The controller 340 outputs a gate control signal GCS for controlling the gate driver 320 and a data control signal DCS for controlling the data driver 330 by using a signal supplied from an external system not shown. Also, the controller 340 samples input image data input from the external system, realigns the sampled data and supplies the realigned digital image data RGB to the data driver 330.

The gate control signal GCS includes a gate start pulse (GSP), a gate shift clock (GSC), a gate output enable signal (GOE), a start signal (Vst) and a gate clock (GCLK). Also, control signals for controlling a shift register may be included in the gate control signal GCS. The data control signal DCS includes a source start pulse (SSP), a source shift clock signal (SSC), a source output enable signal (SOE) and a polarity control signal (POL).

The data driver 330 supplies a data voltage to the data lines DL of the display panel 310. For example, the data driver 330 may convert the image data RGB input from the controller 340 into an analog data voltage and supply the data voltage to the data lines DL.

According to one embodiment of the present disclosure, the gate driver 320 may be packaged on the display panel 310. In this way, a structure in which the gate driver 320 is directly packaged on the display panel 310 will be referred to as a Gate In Panel (GIP) structure. For example, in a Gate In Panel (GIP) structure, the gate driver 320 may be disposed on the base substrate 110.

The display apparatus 1000 according to one embodiment of the present disclosure may include the above-described thin film transistors 100, 200, and 300. According to one embodiment of the present disclosure, the gate driver 320 may include the above-described thin film transistors 100, 200, and 300.

The gate driver 320 may include a shift register 350. The shift register 350 sequentially supplies gate pulses to the gate lines GL for one frame by using the start signal and the gate clock, which are transmitted from the controller 340. In this case, one frame means a time period at which one image is output through the display panel 310. The gate pulse has a turn-on voltage capable of turning on a switching device (thin film transistor) disposed in the pixel P.

Also, the shift register 350 supplies a gate-off signal capable of turning off the switching device, to the gate line GL for the other period of one frame, at which the gate pulse is not supplied. Hereinafter, the gate pulse and the gate-off signal will be collectively referred to as a scan signal SS or Scan. The shift register 350 may include the above-described thin film transistors 100, 200, and 300.

FIG. 7 is a circuit view illustrating any one pixel P of FIG. 6. The circuit view of FIG. 7 is an equivalent circuit view for the pixel P of the display apparatus 1000 that includes an organic light emitting diode (OLED) as a display element 710.

With reference to FIG. 7, the pixel P includes a display element 710 and a pixel driving circuit PDC for driving the display element 710. In detail, the display apparatus 1000 according to one embodiment of the present disclosure may include a pixel driving circuit PDC on the base substrate 110.

The pixel driving circuit PDC of FIG. 7 includes a first thin film transistor TR1 that is a switching transistor and a second thin film transistor TR2 that is a driving transistor. The display apparatus 1000 according to another embodiment of the present disclosure may include at least one of the above-described thin film transistors 100, 200, and 300.

The first thin film transistor TR1 is connected to the gate line GL and the data line DL, and is turned on or off by the scan signal SS supplied through the gate line GL. The data line DL provides a data voltage Vdata to the pixel driving circuit PDC, and the first thin film transistor TR1 controls applying of the data voltage Vdata.

The driving power line PL provides a driving voltage Vdd to the display element 710, and the first thin film transistor TR1 controls the driving voltage Vdd. The driving voltage Vdd is a pixel driving voltage for driving the organic light emitting diode (OLED) that is the display element 710.

When the first thin film transistor TR1 is turned on by the scan signal SS applied from the gate driver 320 through the gate line GL, the data voltage Vdata supplied through the data line DL is supplied to a gate electrode of the second thin film transistor TR2 connected to the display element 710. The data voltage Vdata is charged in a storage capacitor C1 formed between the gate electrode and a source electrode of the second thin film transistor TR2.

The amount of a current supplied to the organic light emitting diode (OLED), which is the display element 710, through the second thin film transistor TR2 is controlled in accordance with the data voltage Vdata, whereby a gray scale of light output from the display element 710 may be controlled.

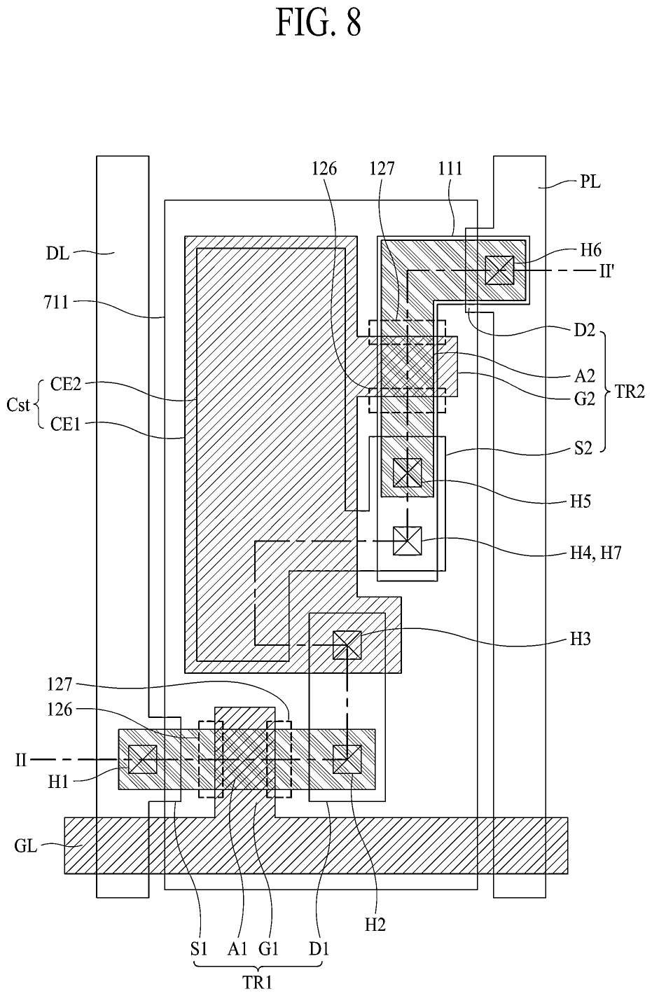

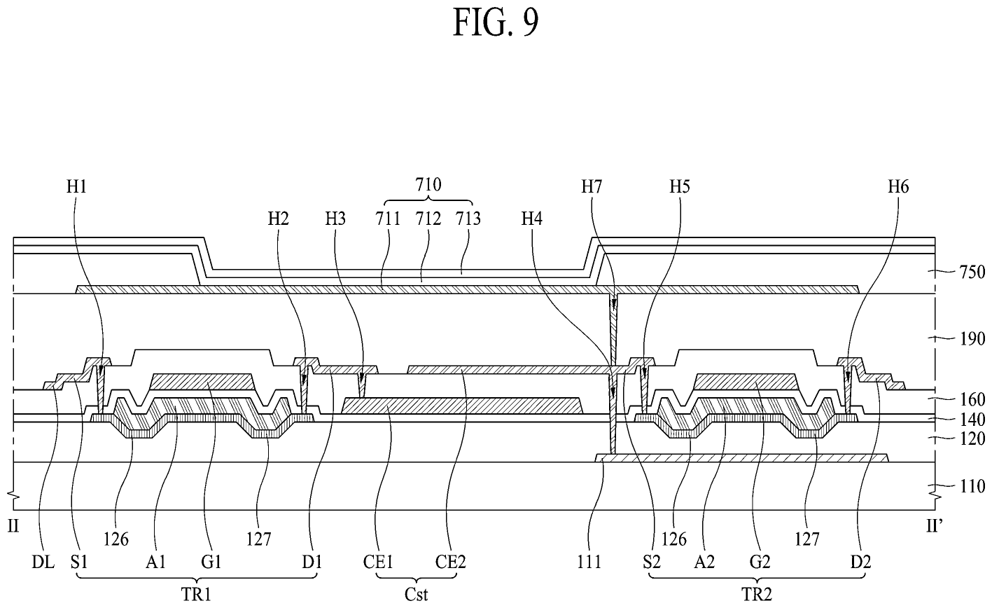

FIG. 8 is a plan view of the pixel of FIG. 7, and FIG. 9 is a cross-sectional view taken along line II-II′ of FIG. 8.

In FIGS. 8 and 9, the first thin film transistor TR1 and the second thin film transistor TR2 are disposed on the base substrate 110. The base substrate 110 may be made of glass or plastic. As the base substrate 110, plastic having flexible characteristics, for example, polyimide (PI) may be used.

The light blocking layer 111 is disposed on the base substrate 110. The light blocking layer 111 may have light blocking characteristics. The light blocking layer 111 may protect the active layers A1 and A2 by blocking light incident from the outside.

The buffer layer 120 is disposed on the light blocking layer 111. The buffer layer 120 is made of an insulating material and protects the active layers A1 and A2 from moisture or oxygen introduced from the outside.

The buffer layer 120 may include a trench 125. The trench 125 refers to a region partially etched in the buffer layer 120. The trench 125 may include a first trench 126 overlapping the source area and a second trench 127 overlapping the drain area.

A first active layer A1 of the first thin film transistor TR1 and a second active layer A2 of the second thin film transistor TR2 are disposed on the buffer layer 120. The first active layer A1 of the first thin film transistor TR1 and the second active layer A2 of the second thin film transistor TR2 may be disposed on the trench 125.

The first active layer A1 and the second active layer A2 may include, for example, an oxide semiconductor material. The first active layer A1 and the second active layer A2 may be formed of an oxide semiconductor layer made of an oxide semiconductor material.

In the first thin film transistor TR1, the first active layer A1 may include a channel area, a source area, and a drain area. The channel area of the first active layer A1 overlaps the gate electrode G1. According to another configuration, the source area may be referred to as the source electrode S1, and the drain area may be referred to as the drain electrode D1.

In the second thin film transistor TR2, the second active layer A2 may include a channel area, a source area, and a drain area. The channel area of the second active layer A2 overlaps the gate electrode G2. According to another configuration, the source area may be referred to as the source electrode S2, and the drain area may be referred to as the drain electrode D2.

A gate insulating layer 140 is disposed on the active layers A1 and A2. The gate insulating layer 140 covers upper surfaces of the active layers A1 and A2.

The gate insulating layer 140 includes a first gate insulating layer 141 and a second gate insulating layer 142 on the first active layer A1 of the first thin film transistor TR1 and the second active layer A2 of the second thin film transistor TR2.

In this case, the thickness of the first gate insulating layer 141 may be greater than the thickness of the second gate insulating layer 142.

The gate electrode G1 of the first thin film transistor TR1 and the gate electrode G2 of the second thin film transistor TR2 are disposed on the gate insulating layer 140.

Although not shown in the drawings, a gate line GL may be disposed on the gate insulating layer 140. The gate electrode G1 of the first thin film transistor TR1 may extend from the gate line GL or may be a part of the gate line GL.

With reference to FIGS. 8 and 9, the first capacitor electrode CE1 of the storage capacitor Cst is formed on the gate insulating layer 140. The first capacitor electrode CE1 may be formed of the same material as the gate electrodes G1 and G2 by the same process. An interlayer insulating layer 160 is disposed on the gate electrodes G1 and G2 and the first capacitor electrode CE1.

The data line DL and the driving power line PL are disposed on the interlayer insulating layer 160. Also, on the interlayer insulating layer 160, the source electrode S1 and the drain electrode D1 of the first thin film transistor TR1 are disposed and the source electrode S2 and the drain electrode D2 of the second thin film transistor TR2 are disposed.

The source electrode S1 of the first thin film transistor TR1 may be integrally formed with the data line DL and may have a structure extending from the data line DL.

The source electrode S1 of the first thin film transistor TR1 may be in contact with a side surface of the active layer A1 of the first thin film transistor TR1 through the first contact hole H1.

The drain electrode D1 of the first thin film transistor TR1 is in contact with the other side surface of the active layer A1 of the first thin film transistor TR1 through the second contact hole H2. Also, the drain electrode D1 of the first thin film transistor TR1 is connected to the first capacitor electrode CE1 through the third contact hole H3. As a result, the first capacitor electrode CE1 may be connected to the first thin film transistor TR1.

The drain electrode D2 of the second thin film transistor TR2 may be integrally formed with the driving power line PL, and may have a structure extending from the driving power line PL.

The drain electrode D2 of the second thin film transistor TR2 may be in contact with a side surface of the active layer A2 of the second thin film transistor TR2 through the sixth contact hole H6.

The source electrode S2 of the second thin film transistor TR2 is in contact with the other side surface of the active layer A2 of the second thin film transistor TR2 through the fifth contact hole H5. Also, the source electrode S2 of the second thin film transistor TR2 is connected to the light blocking layer 111 through the fourth contact hole H4. The same voltage as that applied to the source electrode S2 of the second thin film transistor TR2 may be applied to the light blocking layer 111 overlapping the second thin film transistor TR2.

The source electrode S2 of the second thin film transistor TR2 may extend onto the interlayer insulating layer 160 to form the second capacitor electrode CE2 of the storage capacitor Cst. According to an embodiment, the first capacitor electrode CE1 and the second capacitor electrode CE2 may overlap to form the storage capacitor Cst.

In FIGS. 8 and 9, a planarization layer 190 is disposed on the data line DL, the driving power line PL, the source electrodes S1 and S2, the drain electrodes D1 and D2, and the second capacitor electrode CE2. The planarization layer 190 planarizes upper portions of the first thin film transistor TR1 and the second thin film transistor TR2 and protects the first thin film transistor TR1 and the second thin film transistor TR2. The planarization layer 190 serves as a protection layer.

A first electrode 711 of the display element 710 is disposed on the planarization layer 190. The first electrode 711 of the display element 710 is in contact with the second capacitor electrode CE2 through a seventh contact hole H7 formed in the planarization layer 190. As a result, the first electrode 711 of the display element 710 may be connected to the source electrode S2 of the second thin film transistor TR2.

The bank layer 750 is disposed at an edge of the first electrode 711. The bank layer 750 defines a light emitting area of the display element 710.

The organic light emitting layer 712 is disposed on the first electrode 711, and the second electrode 713 is disposed on the organic light emitting layer 712. Accordingly, the display element 710 is completed. The display element 710 shown in FIG. 7 is an organic light emitting diode (OLED). Therefore, the display apparatus 1000 according to an embodiment may be an organic light emitting display apparatus.

The pixel driving circuit PDC according to another configuration of the present disclosure may be formed in various structures other than the structure described above. The pixel driving circuit PDC may include, for example, three or more thin film transistors.

According to the present disclosure, the following advantageous effects, for example, may be obtained.

The thin film transistor according to an embodiment may include a trench to maintain the length of the effective channel and control or prevent the diffusion of conductorization.

The thin film transistor according to an embodiment may include a trench to prevent or suppress the threshold voltage Vth from being shifted in the negative (−) direction even if the channel area has a short channel.

It will be apparent to those skilled in the art that various modifications and variations can be made in the thin film transistor, the method of manufacturing the same, and the display apparatus including the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor, comprising:
a base substrate;
a buffer layer on the base substrate, an upper surface of the buffer layer having a trench;
an active layer on the buffer layer; and
a gate electrode spaced apart from the active layer and at least partially overlapping the active layer in a plan view;
wherein the active layer includes:
a channel area that overlaps the gate electrode in the plan view;
a source area connected to one side of the channel area in the plan view; and
a drain area connected to the other side of the channel area in the plan view;
wherein the trench includes:
a first trench having the source area therein; and
a second trench having the drain area therein;
wherein the channel area includes:
a first channel area;
a second channel area on one side of the first channel area, in contact with the source area, and in the first trench; and
a third channel area on the other side of the first channel area, in contact with the drain area, and in the second trench;
wherein a shortest distance between an upper surface of the base substrate and the second channel area is shorter than a shortest distance between the upper surface of the base substrate and the first channel area, and
wherein a shortest distance between the upper surface of the base substrate and the third channel area is shorter than the shortest distance between the upper surface of the base substrate and the first channel area.

2. The thin film transistor of claim 1, wherein the first trench and the second trench are spaced apart from each other.

3. The thin film transistor of claim 1, wherein the channel area, the source area, and the drain area of the active layer are integrally formed, and the active layer has a constant thickness.

4. The thin film transistor of claim 1, wherein each of the first trench and the second trench includes:
a first surface substantially parallel to an upper surface of the base substrate;
a second surface connected to one side of the first surface, the second surface inclined at a first angle relative to the first surface; and
a third surface connected to the other side of the first surface, the third surface inclined at a second angle relative to the first surface;
wherein the active layer is on the second surface and the third surface, and
wherein at least a portion of the second surface is overlapped with the gate electrode in the plan view.

5. The thin film transistor of claim 4, wherein the entire second surface of each of the first trench and the second trench is overlapped with the gate electrode.

6. The thin film transistor of claim 1, further including a gate insulating layer between the active layer and the gate electrode,
wherein the gate insulating layer includes:
a first gate insulating layer on the active layer; and
a second gate insulating layer on the first gate insulating layer, and
wherein the first gate insulating layer is on the channel area of the active layer and the trench.

7. The thin film transistor of claim 6, wherein a thickness of the first gate insulating layer is greater than a thickness of the second gate insulating layer.

8. The thin film transistor of claim 6,
wherein the source area includes:
a first source area overlapping the first gate insulating layer and the second gate insulating layer; and
a second source area overlapping the second gate insulating layer without overlapping the first gate insulating layer; and
wherein the drain area includes:
a first drain area overlapping the first gate insulating layer and the second gate insulating layer; and
a second drain area overlapping the second gate insulating layer without overlapping the first gate insulating layer;

9. The thin film transistor of claim 8, wherein the first source area and the first drain area are in contact with the first gate insulating layer, and
wherein the second source area and the second drain area are in contact with the second gate insulating layer.

10. The thin film transistor of claim 1, further including a gate insulating layer between the active layer and the gate electrode,
wherein the gate insulating layer covers the channel area and exposes the source area and the drain area.

11. The thin film transistor of claim 8, wherein the second source area has a higher dopant concentration than the first source area, and
wherein the second drain area has a higher dopant concentration than the first drain area.

12. The thin film transistor of claim 8, wherein the first source area and the first drain area have a length of 0.7 μm to 1.0 μm in the longitudinal direction of the channel area in the plan view.

13. The thin film transistor of claim 1, wherein the trench has a height ratio of 0.15 to 0.65,
wherein the height ratio is obtained by dividing the height of the trench by the width of the trench,
wherein the width is the longest length in the longitudinal direction of the channel area in the plan view, and
wherein the height is a difference between a maximum distance and a minimum distance between the upper surface of the buffer layer and the upper surface of the base substrate in a direction perpendicular to the longitudinal direction of the channel area.

14. The thin film transistor of claim 4, wherein each of the first angle and the second angle are between 30° and 45° relative to the first surface.

15. A display apparatus comprising the thin film transistor of claim 1.

16. A manufacturing method of a thin film transistor, comprising:
forming a first insulating material on a base substrate and patterning the first insulating material to form a buffer layer including a trench;
forming an active layer on the buffer layer;
forming a second insulating material on the active layer and forming a first gate insulating layer by patterning the second insulating material;
forming a second gate insulating layer on the first gate insulating layer; and
forming a gate electrode on the second gate insulating layer,
wherein at least a portion of the trench overlaps the gate electrode in a plan view.

17. The manufacturing method of the thin film transistor of claim 16, further including a step of doping the active layer with a dopant after the step of forming the gate electrode.
